(19) United States
(12) Patent Application Publication
(10) Pub. No.: US 2008/0150532 A1
(43) Pub. Date: Jun. 26, 2008

(54) METHOD AND APPARATUS FOR MEASURING T1 RELAXATION

(75) Inventors: Glenn Scott Slavin, Silver Spring, MD (US); Sandeep Narendra Gupta, Hanover, MD (US)

Correspondence Address: PETER VOGEL;GE HEALTHCARE, 3000 N. GRANDVIEW BLVD., SN-477, WAUKESHA, WI, 53188, US

(73) Assignee: GENERAL ELECTRIC COMPANY, Schenectady, NY (US)

(21) Appl. No.: 11/614,593

(22) Filed: Dec. 21, 2006

(51) Int. Cl. G01R 33/50; G01R 33/48

(52) U.S. Cl. 324/318; 702/19

(57) ABSTRACT

A method for rapid measurement of T1 relaxation comprises a gated, multi-time-point saturation-recovery experiment. Each saturation-recovery experiment may include multiple gating intervals to increase dynamic range of the T1 measurement. Multiple saturation-recovery experiments may also be used to improve accuracy and signal-to-noise of the T1 measurement.

### TECHNICAL FIELD

The present invention relates generally to magnetic resonance imaging (MRI) systems and in particular, to a method and apparatus for measuring T1 relaxation with breath-holding and gating compatibility.

### BACKGROUND

Magnetic resonance imaging (MRI) is a medical imaging modality that can create pictures of the inside of a human body without using x-rays or other ionizing radiation. MRI uses a powerful magnet to create a strong, uniform, static magnetic field (i.e., the “main magnetic field”). When a human body, or part of a human body, is placed in the main magnetic field, the nuclear spins that are associated with the hydrogen nuclei in tissue water become polarized. This means that the magnetic moments that are associated with these spins become preferentially aligned along the direction of the main magnetic field, resulting in a small net tissue magnetization along that axis (the “z axis”, by convention). A MRI system also comprises components called gradient coils that produce smaller amplitude, spatially varying magnetic fields when current is applied to them. Typically, gradient coils are designed to produce a magnetic field component that is aligned along the z axis and that varies linearly in amplitude with position along one of the x, y or z axes. The effect of a gradient coil is to create a small ramp on the magnetic field strength and concomitantly on the resonance frequency of the nuclear spins, along a single axis. Three gradient coils with orthogonal axes are used to “spatially encode” the MR signal by creating a signature resonance frequency at each location in the body. Radio frequency (RF) coils are used to create pulses of RF energy at or near the resonance frequency of the hydrogen nuclei. These coils are used to add energy to the nuclear spin system in a controlled fashion. As the nuclear spins then relax back to their rest energy state, they give up energy in the form of an RF signal. This signal is detected by the MRI system and is transformed into an image using a computer and known reconstruction algorithms.

MR images may be created by applying currents to the gradient and RF coils according to known algorithms called “pulse sequences.\’ A pulse sequence diagram may be used to show the amplitude, phase and timing of the various current pulses applied to the gradient and RF coils for a given pulse sequence. The selection of a pulse sequence determines the relative appearance of different tissue types in the resultant images, emphasizing or suppressing tissue types as desired. The inherent MR properties of tissue, most commonly the relaxation times T1 and T2, may be exploited to create images with a desirable contrast between different tissues. For example, in a MR image of a brain, gray matter may be caused to appear either darker or lighter than white matter, according to the MRI system operator's choice of a T1-weighted or T2-weighted pulse sequence. In addition, pulse sequences may be selected to determine a quantitative measure of T1 or T2, or of other quantities related to magnetic properties of tissue.

T1 may be measured, for example, using an “inversion-recovery” pulse sequence. In this pulse sequence, an inversion pulse inverts the “longitudinal” magnetization (i.e. the magnetization due to the net alignment of magnetic moments along z). The longitudinal magnetization then recovers along the positive z-axis during an inversion time interval, TI. At the end of the TI interval, an excitation pulse is played out and a data acquisition is performed. This sequence of an inversion pulse and an excitation/data acquisition is repeated with different phase-encoding steps until enough data has been acquired to reconstruct an image. Multiple images are then acquired at the same location, with each image having a different TI. This allows a different amount of T1 recovery to take place for each image before the magnetization is excited and a signal acquired. In this way, the recovery of longitudinal magnetization of a tissue is sampled with images acquired at multiple time points on the recovery curve. Standard curve-fitting techniques may be used to fit the signal intensity from each image versus TI in order to determine an average T1 either for a region of interest or for each pixel individually. If individual pixel values are calculated, a “T1 map” may be constructed, displaying the average T1 for each pixel in the image. This technique typically requires a total acquisition time of several minutes.

A Look-Locker pulse sequence is a faster version of an inversion-recovery approach. In this pulse sequence, an inversion pulse inverts the longitudinal magnetization, but as the longitudinal magnetization recovers along the positive z-axis, small flip-angle pulses are used to create a small amount of transverse magnetization at multiple time-points along the T1 recovery curve. Gradient echo acquisitions are performed at each of the time-points to sample the magnetization recovery. Although the recovery of the longitudinal magnetization is more complicated for this sequence, it may be expressed using a closed-form equation from which an average T1 may be derived. A variant of the Look-Locker approach may also be used, in which the inversion pulse is replaced by a saturation pulse. Using a saturation pulse significantly reduces acquisition time compared to an inversion-recovery preparation because the need to wait for the longitudinal magnetization to return to equilibrium is obviated.

For some in vivo T1 mapping applications, it is important to acquire the T1 maps as rapidly as possible, in order to minimize image artifacts or errors in the T1 measurement due to motion, such as respiratory motion. When imaging the chest or abdomen, for example, it is preferable to acquire images during a single breath-hold. For applications in tissue where a periodic motion is present, for example, in cardiac or arterial imaging, a T1 mapping application that is compatible with a gating technique is also desirable. Accordingly, it would be desirable to provide a method and apparatus for a multiple time-point saturation-recovery experiment with breath-holding and gating compatibility.

### BRIEF DESCRIPTION OF THE INVENTION

In accordance with an embodiment, a method for measuring T1 relaxation includes applying a magnetic field to a subject, the subject including a plurality of tissues, each tissue characterized by a T1 relaxation time, wherein the magnetic field causes a net longitudinal magnetization in the plurality of tissues, receiving a first trigger signal, in response to the first trigger signal, generating a first saturation radio frequency pulse configured to saturate the longitudinal magnetization from the plurality of tissues, acquiring a first set of magnetic resonance imaging data at a predetermined time delay after the first trigger signal, receiving a second trigger signal, acquiring a second set of magnetic resonance imaging data at the predetermined time delay after the second trigger signal, and calculating at least one T1 relaxation time based on at least the first and second sets of magnetic resonance imaging data.

In accordance with another embodiment, a computer-readable medium having computer-executable instructions for performing a method for measuring T1 relaxation includes program code for receiving a first trigger signal, program code for generating a first saturation radio frequency pulse in response to the first trigger signal, the first radio frequency pulse configured to saturate a longitudinal magnetization in a subject, program code for acquiring a first set of magnetic resonance imaging data at a predetermined time delay after the first trigger signal, program code for receiving a second trigger signal, and program code for acquiring a second set of magnetic resonance imaging data at the predetermined time delay after the second trigger signal.

In accordance with another embodiment, an apparatus for generating a magnetic resonance image includes a magnetic resonance imaging assembly that includes a magnet, a plurality of gradient coils, a radio frequency coil, a radio frequency transceiver system, and a pulse generator module, and a computer system coupled to the magnetic resonance imaging assembly and programmed to perform a first pulse sequence segment that includes a first saturation radio frequency pulse configured to saturate a longitudinal magnetization in a subject, the first saturation radio frequency pulse performed in response to receipt of a first trigger signal, a first data acquisition block configured to acquire magnetic resonance imaging data for a first image at a predetermined time delay after the first trigger signal, and a second data acquisition block configured to acquire magnetic resonance imaging data for a second image at the predetermined time delay after a second trigger signal.

### BRIEF DESCRIPTION OF THE DRAWINGS

Embodiments are illustrated by way of example and not limitation in the figures of the accompanying drawings, in which like reference numerals indicate corresponding, analogous or similar elements, and in which:

FIG. 1 is a schematic block diagram of an exemplary magnetic resonance imaging system;

FIG. 2 is a schematic diagram of a single segmented saturation-recovery experiment comprising multiple gating intervals in accordance with an embodiment;

FIG. 3 is a schematic diagram of an exemplary acquisition scheme for cardiac or vascular T1 mapping in accordance with an embodiment;

FIG. 4 is a graph of a longitudinal magnetization M_{z} for a tissue in accordance with the pulse sequence illustrated in FIG. 3 in accordance with an embodiment; and

FIG. 5 is a pulse sequence diagram of a 2-segment balanced SSFP (Steady-State Free Precession) data acquisition block compatible with the cardiac acquisition scheme shown in FIG. 3 in accordance with an embodiment.

### DETAILED DESCRIPTION

In the following detailed description, numerous specific details are set forth in order to provide a thorough understanding of embodiments. However it will be understood by those of ordinary skill in the art that the embodiments may be practiced without these specific details. In other instances, well-known methods, procedures, components and circuits have not been described in detail so as not to obscure the embodiments.

A gated pulse sequence built on a multiple time-point, saturation-recovery experiment provides a T1 measurement in breath-hold timing. A gating pulse corresponding to a particular point in a periodic motion of an imaging volume triggers the start of a saturation-recovery (SR) experiment, which comprises a saturation pulse, a recovery time, and a magnetic resonance imaging (MRI) “data acquisition block” (i.e., a series of RF and gradient pulses that may be used to acquire MRI data). A single SR experiment may comprise multiple gating intervals after the saturation pulse, each of which contains a single acquisition block. Each acquisition block may start at a different delay after the saturation pulse, thereby sampling the recovery curve at multiple time-points. The use of multiple gating intervals in the same SR experiment increases the dynamic range with which the T1 recovery curve is sampled. The time delay between each data acquisition block and the closest preceding gating pulse is maintained at a constant interval to ensure that all data for a single T1 measurement is acquired at the same point of the periodic motion. For example, in the case of cardiac imaging, a gating pulse is used to trigger the RF pulses and data acquisition blocks in a SR segment such that all MRI data is collected at the same point in the cardiac cycle.

The pulse sequence may additionally utilize multiple SR experiments to increase confidence in the T1 measurement. The timing of the acquisition blocks relative to the recovery curve may be controlled by shifting the data acquisition blocks relative to the saturation pulses. To maintain the timing of the acquisition blocks relative to the gating pulses, the time interval between the gating pulse and the saturation pulse may be modified to compensate for the shift.

To completely fill a k-space for all of the desired time-points within an imaging subject's breath-hold, fast data acquisition techniques may be used such that multiple lines in k-space for the same image are obtained in a single “shot,” (i.e. at the same time-point in the same SR experiment). Single-shot sequences such as single-shot echo-planar imaging (EPI) may be used to obtain complete images in a single repetition of the sequence. Alternatively, segmented acquisitions requiring multiple repetitions of the sequence to obtain all k-space data necessary such as multi-shot EPI, or a balanced steady-state free precession (SSFP) may be used.

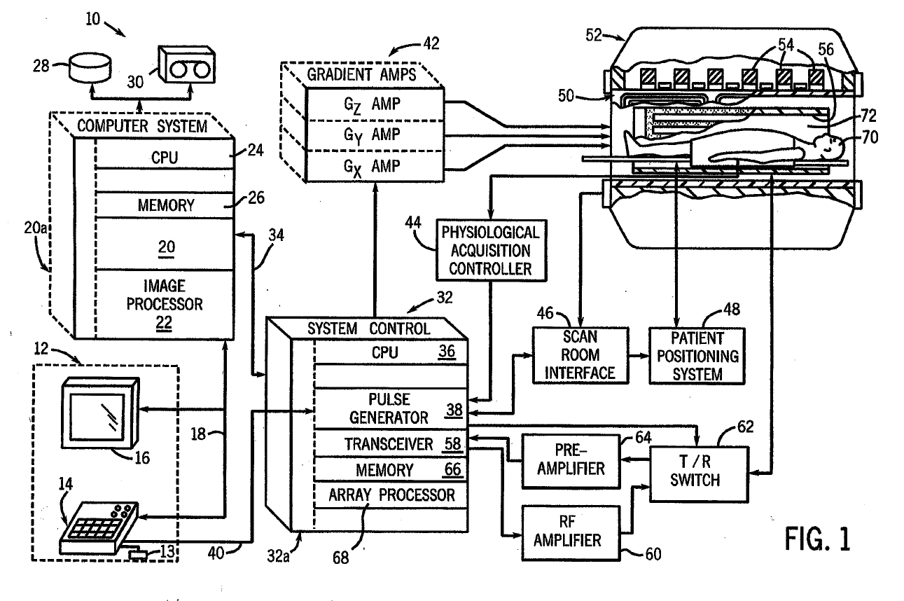

FIG. 1 is a schematic block diagram of an exemplary magnetic resonance imaging system. The operation of MRI system 10 is controlled from an operator console 12 that includes a keyboard or other input device 13, a control panel 14, and a display 16. The console 12 communicates through a link 18 with a computer system 20 and provides an interface for an operator to prescribe MRI scans, display the resultant images, perform image processing on the images, and archive data and images. The computer system 20 includes a number of modules that communicate with each other through electrical and/or data connections, for example such as are provided by using a backplane 20a. Data connections may be direct wired links, or may be fiberoptic connections or wireless communication links or the like. These modules include an image processor module 22, a CPU module 24 and a memory module 26. Memory module 26 may be, for example, a frame buffer for storing image data arrays as known in the art. In an alternative embodiment, the image processor module 22 may be replaced by image processing functionality on the CPU module 24. The computer system 20 is linked to archival media devices, such as disk storage 28 and tape drive 30 for storage of image data and programs, and communicates with a separate system control computer 32 through a link 34. Archival media include, but are not limited to, random access memory (RAM), read-only memory (ROM), electrically erasable programmable ROM (EEPROM), flash memory or other memory technology, compact disk ROM (CD-ROM), digital versatile disks (DVD) or other optical storage, magnetic cassettes, magnetic tape, magnetic disk storage or other magnetic storage devices, or any other medium which may be used to store the desired instructions and which can be accessed by computer system 20, including by internet or other computer network forms of access. The input device 13 can include a mouse, joystick, keyboard, track ball, touch activated screen, light wand, voice control, or any similar or equivalent input device, and may be used for interactive geometry prescription.

The system control computer 32 includes a set of modules in communication with each other via electrical and/or data connections 32a. Data connections 32a may be direct wired links or may be fiberoptic connections or wireless communication links or the like. In alternative embodiments, the modules of computer system 20 and system control computer 32 may be implemented on the same computer systems or a plurality of computer systems. The modules of system control computer 32 include a CPU module 36 and a pulse generator module 38 that connects to the operator console 12 through a communications link 40. It is through link 40 that the system control computer 32 receives commands from the operator to indicate the scan sequence that is to be performed. The pulse generator module 38 operates the system components that play out (i.e., perform) the desired pulse sequence and produces data called RF waveforms which control the timing, strength and shape of the RF pulses to be used, and the timing and length of the data acquisition window. The pulse generator module 38 connects to a gradient amplifier system 42 and produces data called gradient waveforms which control the timing and shape of the gradient pulses that are to be used during the scan. The pulse generator module 38 may also receive patient data from a physiological acquisition controller 44 that receives signals from a number of different sensors connected to the patient, such as ECG signals from electrodes attached to the patient. The pulse generator module 38 connects to a scan room interface circuit 46 that receives signals from various sensors associated with the condition of the patient and the magnet system. It is also through the scan room interface circuit 46 that a patient positioning system 48 receives commands to move the patient table to the desired position for the scan.

The gradient waveforms produced by the pulse generator module 38 are applied to gradient amplifier system 42 which is comprised of Gx, Gy and Gz amplifiers. Each gradient amplifier excites a corresponding physical gradient coil in a gradient coil assembly generally designated 50 to produce the magnetic field gradient pulses used for spatially encoding acquired signals. The gradient coil assembly 50 forms part of a magnet assembly 52 that includes a polarizing magnet 54 and a whole-body RF coil 56. A patient or imaging subject 70 may be positioned within a cylindrical imaging volume 72 of the magnet assembly 52. A transceiver module 58 in the system control computer 32 produces pulses that are amplified by an RF amplifier 60 and coupled to the RF coils 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered and digitized in the receiver section of the transceiver 58. The transmit/receive switch 62 is controlled by a signal from the pulse generator module 38 to electrically connect the RF amplifier 60 to the RF coil 56 during the transmit mode and to connect the preamplifier 64 to the coil during the receive mode. The transmit/receive switch 62 can also enable a separate RF coil (for example, a surface coil) to be used in either the transmit or receive mode.

The MR signals sensed by the RF coil 56 are digitized by the transceiver module 58 and transferred to a memory module 66 in the system control computer 32. MRI data is typically collected in a Fourier space known in imaging as “k-space”, a reciprocal space connected to real space via a Fourier transform. Each MR signal is encoded with a particular spatial frequency using “phase-encoding” gradient pulses, and multiple such MR signals are digitized and stored in k-space for later reconstruction as an image. Typically, frames of data corresponding to MR signals are stored temporarily in the memory module 66 until they are subsequently transformed to create images. An array processor 68 uses a known transformation method, most commonly a Fourier transform, to create images from the MR signals. These images are communicated through the link 34 to the computer system 20 where it is stored in memory, such as disk storage 28. In response to commands received from the operator console 12, this image data may be archived in long term storage, such as on the tape drive 30, or it may be further processed by the image processor 22 and conveyed to the operator console 12 and presented on display 16.

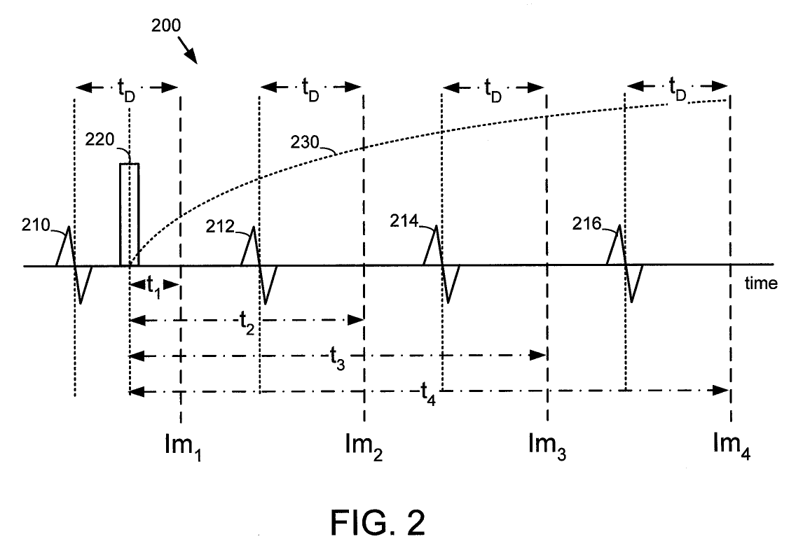

A gated, multiple time-point saturation-recovery (SR) experiment may be used for T1 measurement using the above-described MR system, or any similar or equivalent system for obtaining MR images. FIG. 2 is a schematic diagram of a single SR experiment comprising multiple gating intervals in accordance with an embodiment. The exemplary SR experiment 200 comprises a saturation pulse 220, followed by four gated data acquisition time-points, t₁, t₂, t₃ and t₄, at which time-points, data acquisition blocks are played out to acquire data for images Im₁, Im₂, Im₃ and Im₄ respectively. The T1 recovery curve 230 for longitudinal magnetization (M_{z}) for a tissue of interest is shown after application of the saturation pulse 220. Acquiring images for at least two time-points is required to sample the recovery curve and estimate T1, however, in practice it is more typical to acquire images at 5-10 time-points to increase confidence in the T1 calculation. A saturation pulse may be followed by an arbitrary number of gated data acquisition time-points. An average T1 may be derived within a region of interest in the images, or on a pixel-by-pixel basis, by fitting to a recovery curve the magnetization versus time after the saturation pulse and extracting the T1. A closed-form expression for the magnetization recovery may be derived using the Bloch equations or a discrete computer-modeling approach may be used to calculate T1 as known in the art. T1 maps may be calculated and may be displayed, for example, as a semi-transparent color overlay on a grayscale anatomical image.

Multiple gating pulses, 210, 212, 214 and 216, may be used to trigger the multiple data acquisition time-points after the saturation pulse 220. The gating pulses may be provided by, for example, using an electrocardiograph (ECG) monitor, in which an ECG waveform is collected and used to synchronize the data collection to the cardiac cycle of a patient. Alternatively, any other gating technique may be used. For example, imaging during a repetitive motion of a knee may be accomplished using an external motion-tracking device to provide a trigger at a particular point in the periodic motion. By acquiring data over multiple gating intervals after a single saturation pulse, sufficient dynamic range in the sampling of the T1 recovery curve 230 maybe obtained (i.e., the time delay between Im1 and Im4 may be made sufficiently large compared to the T1 to allow an accurate calculation of the T1). The time delay, t_{D}, between a gating pulse and the next subsequent data acquisition time-point is kept constant for all the gating intervals, such that all data contributing to the four images is acquired at the same phase of the periodic motion.

The SR experiment 200 may be compatible with any type of MRI data acquisition technique, including but not limited to, spin echo (SE), gradient-recalled echo (GRE), fast spin echo (FSE), fast gradient-recalled echo (FGRE), echo-planar imaging (EPI), and steady-state free precession (SSFP) techniques. In one embodiment, a pulse sequence that acquires a single line of k-space per TR, such as SE or GRE, may be used as a data acquisition block such that a single line of k-space is acquired for each image in a SR experiment 200. The SR experiment 200 is then repeated with the data acquisition parameters varied for each SR experiment 200 until k-space is completely filled for all the images corresponding to the data acquisition time-points or until sufficient data has been acquired to allow the use of zero-filling or other reconstruction techniques compatible with an incomplete filling of k-space. In an alternative embodiment, a pulse sequence that acquires multiple lines of k-space per TR, such as FSE, FGRE, multi-shot EPI, or SSFP, may be used as a data acquisition block, such that multiple lines of k-space are acquired for each image in each SR experiment 200. The SR experiment 200 is then repeated with the data acquisition parameters varied for each SR experiment 200 until all required k-space data has been acquired. Typically, sequences that collect multiple k-space lines per SR experiment 200 for each image use a “segmented acquisition” approach, in which k-space is partitioned into multiple k-space segments. The multiple k-space lines that are collected in the same SR experiment 200 are distributed into different k-space segments, such that the k-space lines collected closest to the desired TI are distributed into the k-space segments nearest the center of k-space. Data from successive SR experiments are distributed into the multiple k-space segments until all the segments have been filled. By filling k-space in k-space segments, rather than by using a linear filling scheme, data near the center of k-space may be collected as nearly as possible to the desired TI. Therefore, the reconstructed image contrast will be most strongly weighted by the desired TI. In another alternative embodiment, a pulse sequence that acquires a complete k-space in a single SR experiment 200, such as single-shot EPI, may be used as a data acquisition block to collect all the data required. In this embodiment, all the required k-space lines for Im₁ are collected in a time interval centered at t₁ (shown in FIG. 2) in a single SR experiment. Likewise all the required k-space lines for Im₂ are collected near t₂, and so on for the remaining two images. After data collection for all the images has been completed, the images are reconstructed using known reconstruction algorithms.

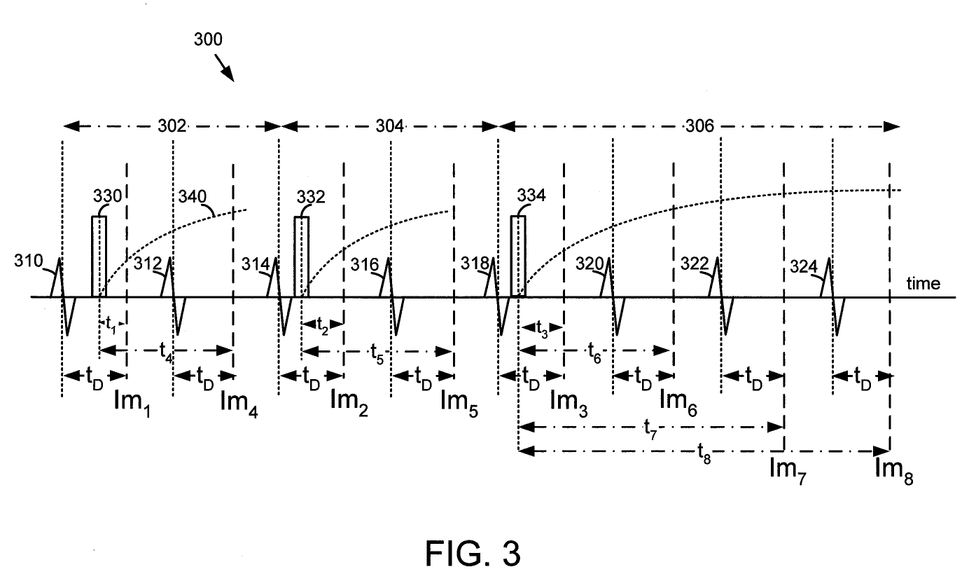

FIG. 3 is a schematic diagram of an exemplary acquisition scheme for cardiac or vascular T1 mapping in accordance with an embodiment. In the exemplary acquisition scheme 300, three SR experiments, 302, 304 and 306, are used, made up of 2, 2, and 4 cardiac cycles, respectively. Each of the three SR experiments, 302, 304 and 306 is a gated saturation recovery SR pulse sequence experiment with multiple gating intervals as described above with respect to FIG. 2. The three SR experiments, 302, 304 and 306, may be used to acquire data for eight images, Im₁ to Im₈. The first SR experiment 302 acquires data for the first and fourth images, Im₁ and Im₄. The second SR experiment 304 acquires data for the second and fifth images, Im₂ and Im₅. The third SR experiment 306 acquires data for the third, sixth, seventh and eighth images, Im₃, Im₆, Im₇ and Im₈.

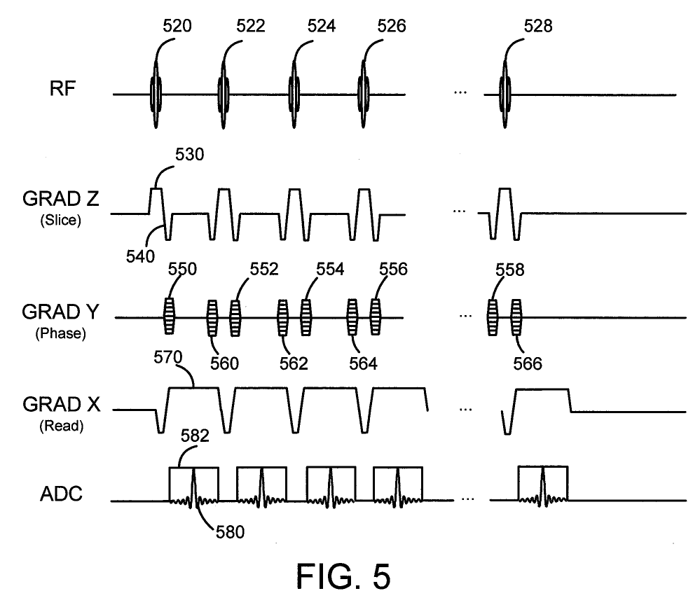

In the first SR experiment 302 which begins with a first ECG trigger 310, a first nonselective saturation pulse 330 is played out (i.e., applied), and one half of k-space for Im1 is acquired after a predetermined delay time, t_{D}, from the first ECG trigger 310 using a two-segment balanced SSFP sequence that is described further below with respect to FIG. 5. The MRI data for Im₁ is acquired at a time-point t₁ after the first saturation pulse 330. After a second ECG trigger 312, no saturation pulse is played out. At a time delay, t_{D}, after the second ECG trigger 312, data is acquired for Im₄ at time t₄=(t₁+RR) after the first saturation pulse 330, where RR is the duration of a cardiac cycle.

In the second SR segment 304 which begins with a third ECG trigger 314, data for Im₂ is acquired at t₂ after a second saturation pulse 332. The second saturation pulse 332 is played out at an interval after the ECG trigger 314 reduced by t₁ compared to the interval between the ECG trigger 310 and the first saturation pulse 330, in order to maintain the delay at t_{D} between the data acquisition block for Im2 and the ECG trigger 314. In the second cardiac cycle of this second SR segment, which begins with ECG trigger 316, data is acquired for Im₅ at t₅=(t₂+RR) after the saturation pulse 332.

In the third SR segment 306, which begins with a fifth ECG trigger 318, data for Im₃ is acquired at t₃ after a third saturation pulse 334. The third saturation pulse 334 is played out at a modified interval after the ECG trigger 318, compared to the interval between the ECG trigger 310 and the first saturation pulse 330, in order to maintain the delay at t_{D} between the data acquisition block for Im2 and the ECG trigger 314. In the second cardiac cycle of this third SR segment, which begins with ECG trigger 320, data is acquired for Im₆ at t₆=(t₃+RR) after the saturation pulse 334. In the third cardiac cycle of this third SR segment, which begins with ECG trigger 322, data is acquired for Im₇ at t₇=(t₃+2RR) after the saturation pulse 334. In the fourth cardiac cycle of this third SR segment, which begins with ECG trigger 324, data is acquired for Im₈ at t₈=(t₃+3RR) alter the saturation pulse 334.

Use of a 2-segment pulse sequence such as a 2-segment balanced SSFP sequence requires that these eight data acquisitions be repeated over the next eight subsequent cardiac cycles to acquire the second half of k-space. In an example, with a heart rate of 60 beats per minute (i.e., RR=1000 ms), and t_{D}=100 ms, after sorting and merging the datasets, eight images are generated at time-points 100 ms, 200 ms, 300 ms, 1100 ms, 1200 ms, 1300 ms, 2300 ms, and 3300 ms. In this example, the total acquisition time for the eight images is 16 s, which is achievable within a breath-hold for most patients.

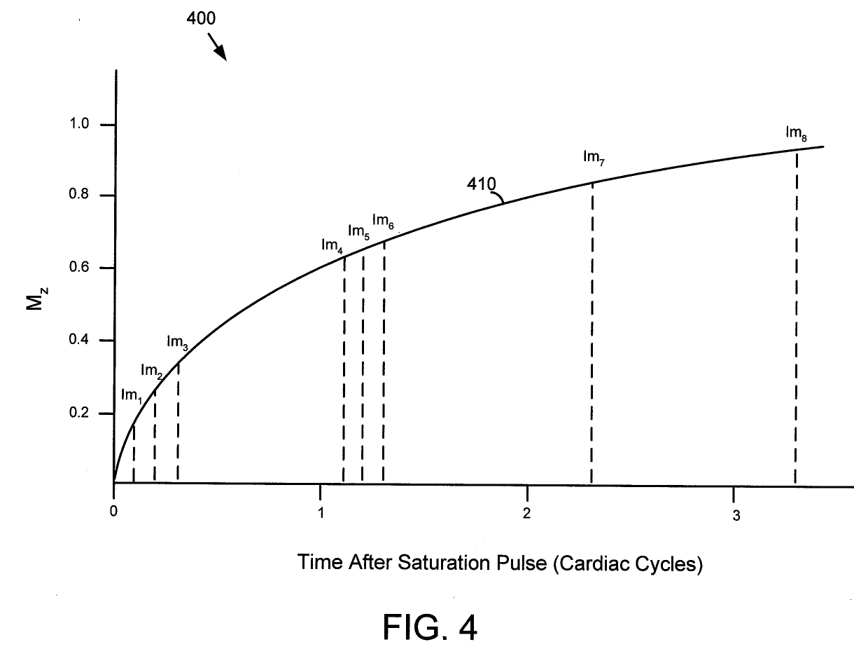

FIG. 4 is a graph of a longitudinal magnetization M_{z} for a tissue in accordance with the pulse sequence illustrated in FIG. 3 in accordance with an embodiment. The graph 400 plots a recovery curve 410 of the longitudinal magnetization, M_{z}, versus time after a saturation pulse, in units of cardiac cycles. The time-points for the eight images, Im₁-Im₈, at which the recovery curve 410 is sampled are shown. Standard T1 calculation techniques may be used to calculate T1 maps from the images as described above with respect to FIG. 2. T1 mapping may be used in the context of myocardial infarct assessment using a MR T1 contrast agent. Tissue with reduced T1 typically corresponds to infarcted areas of the myocardium. The T1 maps of the myocardium may be displayed as a semi-transparent color overlay on a grayscale anatomical image of the heart.

The number of SR experiments to be used for a gated, saturation-recovery Look-Locker pulse sequence, the choice of time-points at which the recovery curve will be sampled, and the segmentation factor for the acquisition scheme may all be chosen to tailor the pulse sequence to the particular application at hand. For example, the tissue T1 is a factor when determining time-points for image acquisition. The tissue T1 and the signal-to-noise ratio available from the tissue of interest are factors when determining the number of SR experiments as well as the number of time points per SR experiment to be used. The signal-to-noise ratio and other imaging considerations may be used to help determine which particular acquisition technique is most suitable for the application.

As mentioned above, a data acquisition technique such as a two-segment balanced SSFP sequence may be used to acquire the MRI data during the SR experiments. FIG. 5 is a pulse sequence diagram of a 2-segment balanced SSFP data acquisition block compatible with the cardiac acquisition scheme shown in FIG. 3 in accordance with an embodiment. In a balanced SSFP acquisition, the net gradient area on each of the logical axes is zero for every TR interval. Radiofrequency (RF) excitation pulses 520, 522, 524, 526 and 528, create transverse magnetization. Slice-selective gradients, for example, 530, are “played out” (i.e., “performed”, or “applied”) during the excitation pulses 520-528. Refocusing lobes, for example, 540, are played out after each slice-selective gradient pulse. Phase-encoding gradient waveforms 550, 552, 554, 556 and 558, are played out in each TR, and oppositely signed phase-rewinding gradients 560, 562, 564, and 566 are also played out in each TR such that the net accrued phase in each TR is zero across the entire image. A read gradient, for example, 570, is played out during an acquisition window, for example, 582, centered in each TR. A free induction decay (FID) signal and an echo signal overlap during each TR interval to produce an echo 580 in the acquisition window 582. The balanced SSFP acquisition is useful for producing images with bright signal from fluids and fat and produces images with higher SNR than other gradient-recalled echo techniques.

The gated, saturation-recovery pulse sequence described herein is compatible with parallel imaging techniques. Parallel imaging techniques may be used with phased array coils to reduce scan time for a fixed spatial resolution. By reducing scan time, it is possible to reduce breath-hold times for the sequence. Alternatively, use of parallel imaging techniques allows acquisition of higher resolution images in the same scan time.

Computer-executable instructions for performing a pulse sequence according to the above-described method may be stored on a form of computer readable media. Computer readable media includes volatile and nonvolatile, removable and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital versatile disks (DVD) or other optical storage, magnetic cassettes, magnetic tape, magnetic disk storage or other magnetic storage devices, or any other medium which can be used to store the desired instructions and which may be accessed by MRI system 10 (shown in FIG. 1), including by internet or other computer network forms of access.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. The order and sequence of any process or method steps may be varied or re-sequenced according to alternative embodiments.

Many other changes and modifications may be made to the present invention without departing from the spirit thereof. The scope of these and other changes will become apparent from the appended claims.

We claim:

1. A method for measuring T1 relaxation, the method comprising:
applying a magnetic field to a subject, the subject comprising a plurality of tissues, each tissue characterized by a T1 relaxation time, wherein the magnetic field causes a net longitudinal magnetization in the plurality of tissues;
receiving a first trigger signal;
in response to the first trigger signal, generating a first saturation radio frequency pulse configured to saturate the longitudinal magnetization from the plurality of tissues;
acquiring a first set of magnetic resonance imaging data at a predetermined time delay after the first trigger signal;
receiving a second trigger signal;
acquiring a second set of magnetic resonance imaging data at the predetermined time delay after the second trigger signal; and
calculating at least one T1 relaxation time based on at least the first and second sets of magnetic resonance imaging data.

2. A method according to claim 1, further comprising:
receiving a third trigger signal;
generating a second saturation radio frequency pulse configured to saturate the longitudinal magnetization from the plurality of tissues;
acquiring a third set of magnetic resonance imaging data at the predetermined time delay after the third trigger signal; and
calculating at least one T1 relaxation time based on at least the first, second, and third sets of magnetic resonance imaging data.

3. A method according to claim 1, wherein the trigger signals are derived from electrocardiograph data.

4. A method according to claim 1, further comprising calculating a T1 map.

5. A method according to claim 1, wherein acquiring a first set of magnetic resonance imaging data and acquiring a second set of magnetic resonance imaging data comprises performing a fast gradient-recalled echo pulse sequence.

6. A method according to claim 5, wherein the fast gradient-recalled echo pulse sequence is a steady-state free precession pulse sequence.

7. A method according to claim 1, wherein the method for measuring T1 relaxation is performed during a breath-hold time associated with the subject.

8. A method according to claim 1, wherein the at least one T1 relaxation time is for myocardial tissue.

9. A computer-readable medium having computer-executable instructions for performing a method for measuring T1 relaxation, the computer-readable medium comprising:
program code for receiving a first trigger signal;
program code for generating a first saturation radio frequency pulse in response to the first trigger signal, the first radio frequency pulse configured to saturate a longitudinal magnetization in a subject;
program code for acquiring a first set of magnetic resonance imaging data at a predetermined time delay after the first trigger signal;
program code for receiving a second trigger signal; and
program code for acquiring a second set of magnetic resonance imaging data at the predetermined time delay after the second trigger signal.

10. A computer-readable medium according to claim 9, further comprising:
program code for receiving a third trigger signal;
program code for generating a third saturation radio frequency pulse in response to the third trigger signal, the third saturation radio frequency pulse configured to saturate the longitudinal magnetization in the subject; and
program code for acquiring a third set of magnetic resonance imaging data at the predetermined time delay after the third trigger signal.

11. An apparatus for generating a magnetic resonance image, the apparatus comprising:
a magnetic resonance imaging assembly comprising a magnet, a plurality of gradient coils, a radio frequency coil, a radio frequency transceiver system, and a pulse generator module; and
a computer system coupled to the magnetic resonance imaging assembly and programmed to perform a first pulse sequence segment comprised of:
a first saturation radio frequency pulse configured to saturate a longitudinal magnetization in a subject, the first saturation radio frequency pulse performed in response to receipt of a first trigger signal;
a first data acquisition block configured to acquire magnetic resonance imaging data for a first image at a predetermined time delay after the first trigger signal; and
a second data acquisition block configured to acquire magnetic resonance imaging data for a second image at the predetermined time delay after a second trigger signal.

12. An apparatus according to claim 11, wherein the computer system coupled to the magnetic resonance imaging assembly is programmed additionally to perform a second pulse sequence segment comprised of:
a second saturation radio frequency pulse configured to saturate the longitudinal magnetization in the subject, the second saturation radio frequency pulse performed in response to receipt of a third trigger signal; and
a third data acquisition block configured to acquire magnetic resonance imaging data for a third image at the predetermined time delay after the third trigger signal.

13. An apparatus according to claim 11, wherein the first data acquisition block and the second data acquisition block comprise a fast gradient-recalled echo pulse sequence.

14. An apparatus according to claim 13, wherein the fast gradient-recalled echo pulse sequence is a steady-state free precession pulse sequence.

15. An apparatus according to claim 11, wherein the first trigger signal and the second trigger signal are derived from electrocardiograph data.
